(19) United States
(12) Patent Application Publication
(10) Pub. No.: US 2026/0136820 A1
(43) Pub. Date: May 14, 2026

(54) ELECTRONIC DEVICE USING SELF-HEALING BIODEGRADABLE ELASTIC CONDUCTOR AND METHOD FOR MANUFACTURING THE SAME

(71) Applicant: KOREA UNIVERSITY RESEARCH AND BUSINESS FOUNDATION, Seoul (KR)

(72) Inventors: Suk Won HWANG, Seoul (KR); Won Bae HAN, Seoul (KR); Tae Min JANG, Seoul (KR)

(73) Assignee: KOREA UNIVERSITY RESEARCH AND BUSINESS FOUNDATION, Seoul (KR)

(21) Appl. No.: 19/306,240

(22) Filed: Aug. 21, 2025

(30) Foreign Application Priority Data
Nov. 13, 2024 (KR) 10-2024-0161437

(51) Int. Cl. H10K 71/12; H10K 71/40; H10K 71/60; H10K 85/10

(52) U.S. Cl. CPC H10K 71/12; H10K 71/40; H10K 71/60; H10K 85/1135

(57) ABSTRACT

Disclosed are an electronic device using a self-healing biodegradable elastic conductor and a method for manufacturing the same. he method for manufacturing the electronic device using the self-healing biodegradable elastic conductor includes: preparing a base film; forming an electrode pattern by spin-coating a conductive polymer solution on the base film; and annealing the electrode pattern, wherein the base film is manufactured from a polymer formed by bonding diisocyanate to both ends of a biodegradable polymer and bonding a chain extender having a disulfide bond structure to an end of the diisocyanate, and the conductive polymer solution is a mixed solution of a conductive polymer, an ionic liquid, polyethylene glycol, and glycerol.

### CROSS-REFERENCE TO RELATED APPLICATION(S)

This application claims the benefit under 35 USC 119(a) of Korean Patent Application No. 10-2024-0161437, with the Korean Intellectual Property Office filed on Nov. 13, 2024, the disclosure of which is incorporated herein by reference in its entirety.

### BACKGROUND OF THE INVENTION

### 1. Field of the Invention

The present invention relates to an electronic device using a self-healing biodegradable elastic conductor and a method for manufacturing the same, and more particularly, to an electronic device using a self-healing biodegradable elastic conductor, inserted into a living body to function stably and having a recovering function against physical and/or electrical damage, and a method for manufacturing the same.

### 2. Description of the Related Art

Transient electronics is a technology of stably performing an original function of an element for a predetermined period of time and then being dissolved/degraded/separated in the body or environment, thereby losing the physical state and electrical function, and has brought innovation to the fields of biomedical and eco-friendly electronic systems.

The transient electronics is generally applied to the skin and body organs through an attachable and implantable form, and flexibility and stretchability of the element are essentially required so as to minimize damage to living tissue during the applied process and ensure that the device operates stably even when the living tissue is frequently moved and deformed.

Meanwhile, since it may be impossible or difficult to repair an element implanted in a living body when malfunction occurs in the element, long-term stable operation of the element is a very important technological challenge. Self-healing materials have been introduced as a solution for the problem, however, there are still limitations in terms of biodegradability, mechanical properties, durability, and processability.

In addition, in order to implement a self-healing bio-implantable electronic device capable of reliably performing advanced functions, both the polymer material serving as a substrate and a protective film for an electronic element and the conductive layer material for an element of the electronic device and electrical connections are required to have self-healing functions, and element technology is required to realize strong bonding properties between two materials so as to achieve stable operation.

Thus, researches are required to solve the above-described problems.

### SUMMARY OF THE INVENTION

The present invention provides a method for manufacturing an electronic device using a self-healing biodegradable elastic conductor having biodegradability, elasticity and conductivity.

In addition, the present invention provides an electronic device using a self-healing biodegradable elastic conductor having a self-recover function from physical or electrical damage.

In addition, the present invention provides an electronic device using a self-healing biodegradable elastic conductor allowed to be inserted and/or implanted in a living body.

In addition, the present invention provides an electronic device using a self-healing biodegradable elastic conductor having an excellent adhesion strength between a base film and an electrode pattern.

An electronic device using a self-healing biodegradable elastic conductor and a method for manufacturing the same according to the present invention include: preparing a base film; forming an electrode pattern by spin-coating a conductive polymer solution on the base film; and drying the electrode pattern, wherein the base film may be manufactured from a polymer formed by bonding diisocyanate to both ends of a biodegradable polymer and bonding a chain extender having a disulfide bond structure to an end of the diisocyanate, and the conductive polymer solution may be a mixed solution of a conductive polymer, an ionic liquid, polyethylene glycol, and glycerol.

In addition, the biodegradable polymer may be poly(L-lactide-co-ε-caprolactone) (PLCL), the diisocyanate may be isophorone diisocyanate (IPDI), and the chain extender may be Bis(4-aminophenyl)disulfide molecule (AFD).

In addition, the conductive polymer may be at least one selected from PEDOT:PSS, polypyrrole (PPy), and polyaniline (PANI), and the ionic liquid may be P14[TFSI](N-methyl-N-butylpyrrolidinium bis(trifluoromethanesulfonyl)imide).

In addition, the conductive polymer, the ionic liquid, the polyethylene glycol, and the glycerol may be mixed in a ratio of 1:2:4:5.

In addition, the annealing may include heat-treating the base film and the electrode pattern at a temperature range of 130° C. to 150° C.

In addition, the base film may have a thickness of 10 μm to 500 μm, and the electrode pattern may have a thickness of 0.1 μm to 5 μm.

The electronic device using a self-healing biodegradable elastic conductor according to the present invention includes: a first base film; and a first electrode pattern adhering to an upper surface of the first base film, wherein the first base film may be manufactured from a polymer formed by bonding diisocyanate to both ends of a biodegradable polymer and bonding a chain extender having a disulfide bond structure to an end of the diisocyanate, and the first electrode pattern may be formed by spin-coating a conductive polymer solution obtained by mixing a conductive polymer, an ionic liquid, polyethylene glycol, and glycerol onto the upper surface of the first base film.

In addition, the electronic device further includes: a second base film provided on an upper portion of the first electrode pattern; and a second electrode pattern adhering to an upper surface of the second base film, wherein the second base film may be manufactured from a polymer formed by bonding diisocyanate to both ends of a biodegradable polymer and bonding a chain extender having a disulfide bond structure to an end of the diisocyanate, and the second electrode pattern may be formed by spin-coating a conductive polymer solution obtained by mixing a conductive polymer, an ionic liquid, polyethylene glycol, and glycerol onto the upper surface of the second base film.

In addition, the biodegradable polymer may be poly(L-lactide-co-ε-caprolactone) (PLCL), the diisocyanate may be isophorone diisocyanate (IPDI), the chain extender may be Bis(4-aminophenyl)disulfide molecule (AFD), the conductive polymer may be at least one selected from PEDOT:PSS, polypyrrole (PPy), and polyaniline (PANI), and the ionic liquid may be P14[TFSI](N-methyl-N-butylpyrrolidinium bis(trifluoromethanesulfonyl)imide).

In addition, the first base film may have a thickness of 10 μm to 500 μm, and the first electrode pattern may have a thickness of 0.1 μm to 5 μm.

According to the present invention, the first base film formed with the first electrode pattern and the second base film formed with the second electrode pattern are bonded, so that a self-healing electronic device to be inserted and/or implanted in a living body can be manufactured.

In addition, according to the present invention, the first base film formed with the first electrode pattern and the second base film formed with the second electrode pattern are self-healed when being damaged, so that the stability of physical/electrical performance can be improved.

In addition, according to the present invention, temperature, humidity, and pressure in the living body can be monitored through the first electrode pattern and the second electrode pattern.

In addition, according to the present invention, high adhesion can be achieved through physical and chemical bonding between the base film and the electrode pattern.

### BRIEF DESCRIPTION OF THE DRAWINGS

FIG. 1 is a view showing a structure of an electronic device using a self-healing biodegradable elastic conductor according to the embodiment of the present invention.

FIG. 2 is a view showing a manufacturing process of a first base film of FIG. 1.

FIG. 3 is a flowchart showing a manufacturing process of the electronic device using a self-healing biodegradable elastic conductor according to the embodiment of the present invention.

FIG. 4 is a photograph showing a process of testing a self-healing ability of a first base film according to the embodiment of the present invention.

FIG. 5 is a graph showing the stress-strain ratio according to recovery time of the first base film of FIG. 4.

FIG. 6 is a photograph showing a first electrode pattern according to the embodiment of the present invention.

FIG. 7 is an SEM image showing a change in a section in which the first electrode pattern of FIG. 6 is cut.

FIG. 8 is a graph showing electrical conductivity and recovery time of electrode patterns measured by varying the ratio of polyethylene glycol (PEG).

FIG. 9 is a graph showing electrical conductivity and stretchability of electrode patterns measured by varying the P14[TFSI] ratio.

FIG. 10 is a graph measuring changes in current when repeated damage occurs to the first electrode pattern according to the embodiment of the present invention.

FIG. 11 is a view showing results of a lap-shear test of electronic devices according to a comparative example and the embodiment of the present invention.

FIG. 12A to 12C are views showing physical bonding between the first base film and the first electrode pattern according to the embodiment of the present invention.

FIG. 13 is a view showing molecular structures of the first base film and the first electrode pattern according to the embodiment of the present invention.

FIG. 14A to 14C are views showing results of a self-healing ability experiment of a specimen manufactured according to the embodiment of the present invention.

FIG. 15A to 15C are views showing results of testing physical and electrical stability under aqueous conditions of electronic devices using self-healing biodegradable elastic conductors according to the embodiment of the present invention and the comparative example.

FIG. 16A to 16D are views showing the electronic device using the self-healing biodegradable elastic conductor according to the embodiment of the present invention.

FIGS. 17A and 17B are views showing a state in which the electronic device using the self-healing biodegradable elastic conductor according to the embodiment of the present invention is applied inside a living body.

FIG. 18 is a graph showing results of functional recovery for artificial damage to the electric device using the self-healing biodegradable elastic conductor of FIG. 17 while monitoring urination behaviors of a bladder in real time through the electric device.

### DETAILED DESCRIPTION OF THE INVENTION

Hereinafter, exemplary embodiments of the present invention will be described in detail with reference to the accompanying drawings. However, the technical idea of the present invention is not limited to the exemplary embodiments described herein and may be embodied in other forms. Further, the embodiments are provided to enable contents disclosed herein to be thorough and complete and provided to enable those skilled in the art to fully understand the idea of the present invention.

In the specification, when one component is mentioned as being on another component, it signifies that the one component may be placed directly on another component or a third component may be interposed therebetween. In addition, in drawings, thicknesses of films and regions may be exaggerated to effectively describe the technology of the present invention.

In addition, although terms such as first, second and third are used herein to describe various components in various embodiments of the present specification, the components will not be limited by the terms. The above terms are used merely to distinguish one component from another. Accordingly, a first component referred to in one embodiment may be referred to as a second component in another embodiment. Each embodiment described and illustrated herein may also include a complementary embodiment. In addition, the term “and/or” is used herein to include at least one of the components listed before and after the term.

The singular expression herein includes a plural expression unless the context clearly specifies otherwise. In addition, it will be understood that the term such as “include” or “have” herein is intended to designate the presence of feature, number, step, component, or a combination thereof recited in the specification, and does not preclude the possibility of the presence or addition of one or more other features, numbers, steps, components, or combinations thereof. In addition, the term “connection” is used herein to include both indirectly connecting a plurality of components and directly connecting the components.

In addition, in the following description of the embodiments of the present invention, the detailed description of known functions and configurations incorporated herein will be omitted when it possibly makes the subject matter of the present invention unclear unnecessarily.

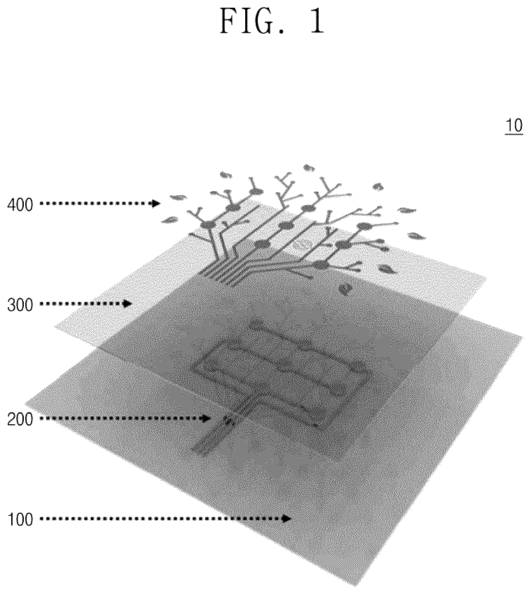

FIG. 1 is a view showing a structure of an electronic device 10 using a self-healing biodegradable elastic conductor according to the embodiment of the present invention.

Referring to FIG. 1, the electronic device 10 using the self-healing biodegradable elastic conductor according to the embodiments of the present invention is provided to have a structure laminated in a direction perpendicular to the ground, and self-heal from physical/electrical damage. The electronic device 10 using the self-healing biodegradable elastic conductor includes a first base film 100, a first electrode pattern 200, a second base film 300, and a second electrode pattern 400.

The first base film 100 serves as a bottom layer and has a predetermined area and a thin thickness. The first base film 100 may be manufactured from a self-healing biodegradable elastic conductor. The first base film 100 may be provided as a polymer configured by bonding diisocyanate to both ends of a biodegradable polymer and bonding a chain extender having a disulfide bond structure to an end of the diisocyanate. According to the embodiment, the first base film 100 may be provided as a polymer having a structure in which isophorone diisocyanate (IPDI) is bonded to both ends of poly(L-lactide-co-ε-caprolactone) (PLCL) and Bis(4-aminophenyl)disulfide molecule (AFD) serving as a chain extender is bonded to both ends of IPDI. According to the embodiment, PLCL may be provided in molecular weights ranging from 500 to 5000.

The first base film 100 may have a thickness of 10 μm to 500 μm, and preferably, have a thickness of 100 μm. The first base film 100 is biodegradability and elasticity.

The first electrode pattern 200 is manufactured from a self-healing, biodegradable, elastic and conductive polymer and formed on an upper surface of the first base film 100. The first electrode pattern 200 may be manufactured by spin-coating a conductive polymer solution on the upper surface of the first base film 100 and performing drying and heat-treating process. According to the embodiment, the conductive polymer solution is prepared by mixing a conductive polymer, an ionic liquid, polyethyleneglycol (PEG), and glycerol.

The first electrode pattern 200 has a predetermined arrangement and is formed to have a thin thickness. According to the embodiment, the first electrode pattern 200 may have a thickness of 0.1 μm to 5 μm, and preferably, have a thickness of 2 μm. The first electrode pattern 200 has biodegradability, elasticity and conductivity.

The second base film 300 is laminated on upper surfaces of the first electrode pattern 200 and the first base film 100.

The second base film 300 may be formed of a self-healable, biodegradable elastic conductor. The second base film 300 may be provided as a polymer configured by bonding diisocyanate to both ends of a biodegradable polymer and bonding a chain extender having a disulfide bond structure to an end of the diisocyanate. According to the embodiment, the second base film 300 may be provided as a polymer having a structure in which isophorone diisocyanate (IPDI) is bonded to both ends of poly(L-lactide-co-ε-caprolactone) (PLCL) and Bis(4-aminophenyl)disulfide molecule (AFD) serving as a chain extender is bonded to both ends of IPDI. According to the embodiment, PLCL may be provided in molecular weights ranging from 500 to 5000.

The second base film 300 may have a thickness of 10 μm to 500 μm. preferably, have a thickness of 100 μm. The second base film 300 is biodegradability and elasticity. According to the embodiment, the second base film 300 is manufactured from the same material as the first base film 100.

The first electrode pattern 400 is manufactured from a self-healing, biodegradable, elastic and conductive polymer and formed on an upper surface of the first base film 300. The second electrode pattern 400 may be manufactured by spin-coating a conductive polymer solution on the upper surface of the first base film 300 and performing drying and heat-treating process. According to the embodiment, the conductive polymer solution is prepared by mixing a conductive polymer, an ionic liquid, polyethyleneglycol (PEG), and glycerol.

The second electrode pattern 400 has a predetermined arrangement and is formed to have a thin thickness. According to the embodiment, the second electrode pattern 400 may have a thickness of 0.1 μm to 5 μm. preferably, have a thickness of 2 μm. The second electrode pattern 400 has biodegradability, elasticity and conductivity. According to the embodiment, the second electrode pattern 400 is formed of the same material as the first electrode pattern 100.

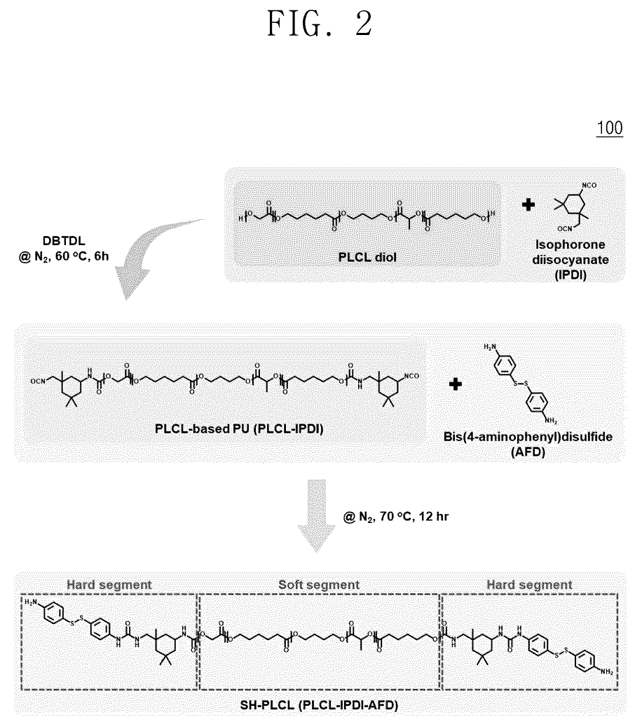

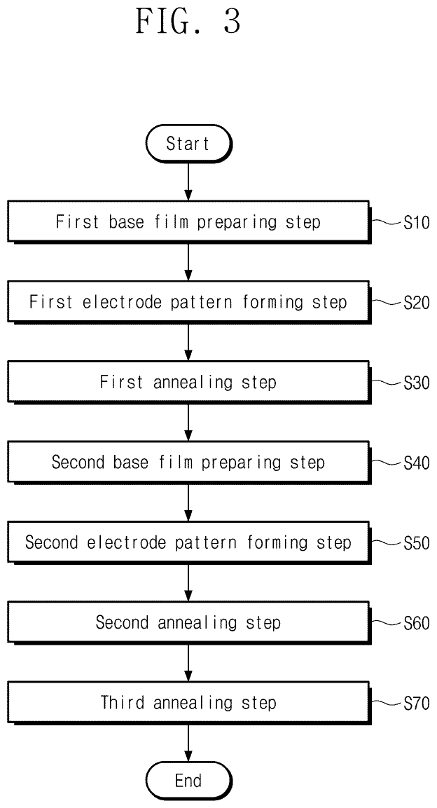

FIG. 2 is a view showing a manufacturing process of the first base film 100 of FIG. 1; and FIG. 3 is a flowchart showing a manufacturing process of the electronic device 10 using the self-healing biodegradable elastic conductor according to the embodiment of the present invention.

Referring to FIGS. 2 and 3, the manufacturing process of the self-healing electronic device 10 according to the embodiment of the present invention includes a first base film preparing step S10, a first electrode pattern forming step S20, a first annealing step S30, a second base film preparing step S40, a second electrode pattern forming step S50, a second annealing step S60, and a third annealing step S70.

In the first base film preparing step S10, a first base film 100 is prepared on a glass substrate cast with PDMS.

The first base film 100 may be manufactured as a polymer formed by bonding diisocyanate to both ends of a biodegradable polymer and bonding a chain extender having a disulfide bond structure to an end of the diisocyanate.

According to the embodiment, the first base film SH-PLCL 100 may be manufactured by bonding isophorone diisocyanate (IPDI) to both ends of poly(L-lactide-co-ε-caprolactone) (PLCL) and then bonding Bis(4-aminophenyl)disulfide molecule (AFD) serving as a chain extender to both ends of IPDI. The first base film SH-PLCL 100 has elasticity, strength, and durability through a structure in which IPDI and AFD as hard segments are bonded to both ends of PLCL as a soft segment.

The first base film SH-PLCL 100 may be manufactured to have a predetermined area and a thin thickness. According to the embodiment, the first base film SH-PLCL 100 may be manufactured to have a thickness of 10 μm to 500 μm, and preferably, manufactured to have a thickness of 100 μm.

In the first electrode pattern forming step S20, a conductive polymer solution is spin-coated on an upper surface of the first base film 100 to form a first electrode pattern 200. The conductive polymer solution is prepared by mixing a conductive polymer, an ionic liquid, polyethyleneglycol (PEG), and glycerol. According to the embodiment, the conductive polymer may be at least one selected from poly(3,4-ethylenedioxythiophene):poly(styrenesulfonate (PEDOT:PSS), polypyrrole (PPy), and polyaniline (PANI), and the ionic liquid is P14[TFSI](N-methyl-N-butylpyrrolidinium bis(trifluoromethanesulfonyl)imide). Preferably, the conductive polymer solution may be obtained by mixing PEDOT:PSS, P14[TFSI], polyethylene glycol and glycerol in the ratio of 1:2:4:5.

In the first electrode pattern forming step S20, a pattern is formed on the upper surface of the first base film 100 through a PDMS stencil mask by using the conductive polymer solution, and then dried on a hot plate at 50° C. for 10 minutes.

The first electrode pattern 200 may have a predetermined arrangement and have a thin thickness. According to the embodiment, the first electrode pattern 200 may be formed to have a thickness of 0.1 μm to 5 μm, and preferably, have a thickness of 2 μm. The first electrode pattern 200 is a lower electrode of the electronic device and serves as a pressure sensor.

In the first annealing step S30, the PDMS stencil mask is removed from the first base film 100 formed thereon with the first electrode pattern 200, and then an annealing process is performed at a temperature of 140° C. for 1 hour. In this process, the first electrode pattern 200 and the first base film 100 are completely dried at a contact area therebetween, and then strongly adhere to each other.

In the second base film preparing step S40, a second base film 300 is prepared on a glass substrate cast with PDMS. The second base film 300 may be manufactured as a polymer formed by bonding diisocyanate to both ends of a biodegradable polymer and bonding a chain extender having a disulfide bond structure to an end of the diisocyanate. According to the embodiment, the second base film 300 may be manufactured by bonding isophorone diisocyanate (IPDI) to both ends of poly(L-lactide-co-ε-caprolactone) (PLCL) and then bonding Bis(4-aminophenyl)disulfide molecule (AFD) serving as a chain extender to both ends of IPDI. The second base film 300 has elasticity, strength, and durability through a structure in which IPDI and AFD as hard segments are bonded to both ends of PLCL as a soft segment.

The second base film 300 may be manufactured to have a predetermined area and a thin thickness. According to the embodiment, the second base film 300 may be manufactured to have a thickness of 10 μm to 500 μm, and preferably, manufactured to have a thickness of 100 μm.

In the second electrode pattern forming step S50, a conductive polymer solution is spin-coated on an upper surface of the second base film to form a second electrode pattern 400. The conductive polymer solution is prepared by mixing a conductive polymer, an ionic liquid, polyethyleneglycol (PEG), and glycerol. According to the embodiment, the conductive polymer may be at least one selected from poly(3,4-ethylenedioxythiophene):poly(styrenesulfonate (PEDOT:PSS), polypyrrole (PPy), and polyaniline (PANI), and the ionic liquid may P14[TFSI](N-methyl-N-butylpyrrolidinium bis(trifluoromethanesulfonyl)imide). Preferably, the conductive polymer solution may be obtained by mixing PEDOT:PSS, P14[TFSI], polyethylene glycol and glycerol in the ratio of 1:2:4:5.

In the second electrode pattern forming step S50, the second electrode pattern 400 having a predetermined shape is formed of the conductive polymer solution by using a PDMS stencil mask, and then dried on a hot plate at 50° C. for 10 minutes.

The second electrode pattern 400 may have a predetermined arrangement and have a thin thickness. According to the embodiment, the second electrode pattern 400 may be formed to have a thickness of 0.1 μm to 5 μm, and preferably, have a thickness of 2 μm. The second electrode pattern 400 is an upper electrode of the electronic device and serves as a humidity sensor, a temperature sensor, and a capacitive pressure sensor.

In the second annealing step S60, the PDMS stencil mask is removed from the second base film 300 formed thereon with the second electrode pattern 400, and then an annealing process is performed at a temperature of 140° C. for 1 hour. In this process, the second electrode pattern 400 and the second base film 300 are completely dried at a contact area therebetween, and then strongly adhere to each other.

In the third annealing step S70, the first base film 100 formed thereon with the first electrode pattern 200 is assembled with the second base film 300 formed thereon with the second electrode pattern 400. A bottom surface of the second base film 300 formed thereon with the second electrode pattern 400 is aligned on the upper surface of the first base film 100 formed thereon with the first electrode pattern 200, and an annealing process is performed by applying a temperature of 80° C. and a pressure of about 100 kPa for 3 hours. In this process, the first base film 100 formed thereon with the first electrode pattern 200 and the second base film 300 formed thereon with the second electrode pattern 400 are bonded as a laminated structure.

A transfer printing process is used to form a protective film on the first base film 100 and the second base film 300 after completion of the bonding.

The above-described electronic device using the self-healing biodegradable elastic conductor may be connected with a flexible anisotropic conductive film (ACF) cable, so as to transmit electrical signals detected from the above sensors to the outside.

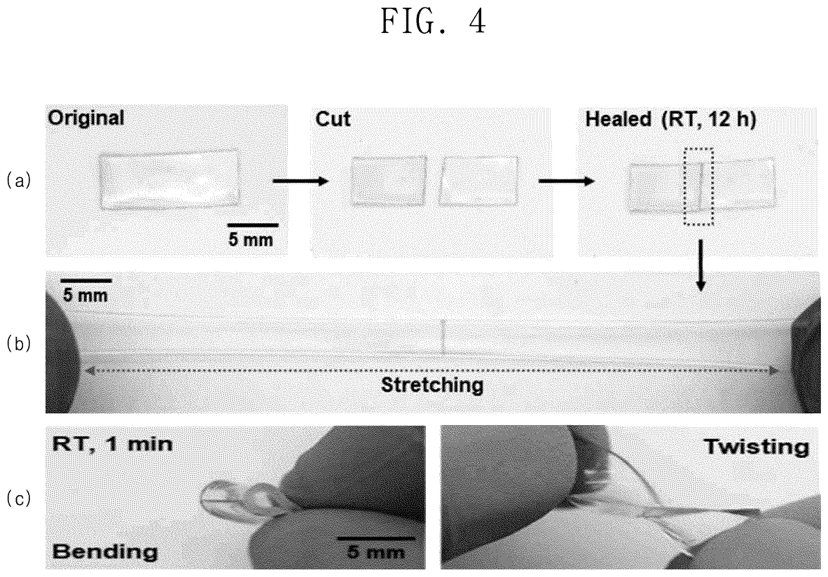

FIG. 4 is a photograph showing a process of testing the self-healing ability of a first base film 100 according to the embodiment of the present invention. FIG. 4(a) shows a state in which the first base film 100 is cut and then bonded; FIG. 4(b) shows a state in which the first base film 100 is bonded and then stretched; and FIG. 4(c) shows a state in which the stretched first base film 100 is healed and then subjected to bending (left) and twisting (right) motions.

Referring to FIG. 4, the first base film 100 according to the embodiment of the present invention is cut and physically bonded at room temperature (RT), and then stretched by about 500% in the longitudinal direction. In addition, after 1 minute is passed since the first base film 100 has been healed, bending and twisting motions are performed on the bonded portion. It is confirmed that separation and/or deformation does not occur at the bonded portion of the first base film 100 regardless of the bending and twisting motions after being physically cut and bonded.

FIG. 5 is a graph showing the stress-strain ratio according to recovery time of the first base film SH-PLCL 100 of FIG. 4.

Referring to FIG. 5, it shows that the first base film SH-PLCL 100 according to the embodiment of the present invention has a recovery efficiency increasing to 80% within 3 hours at room temperature, and reaching about 100% after 12 hours. Accordingly, it can be seen that even when the physical cutting and deformation are applied to the first base film SH-PLCL 100, the mechanical properties are completely recovered after about 12 hours at room temperature.

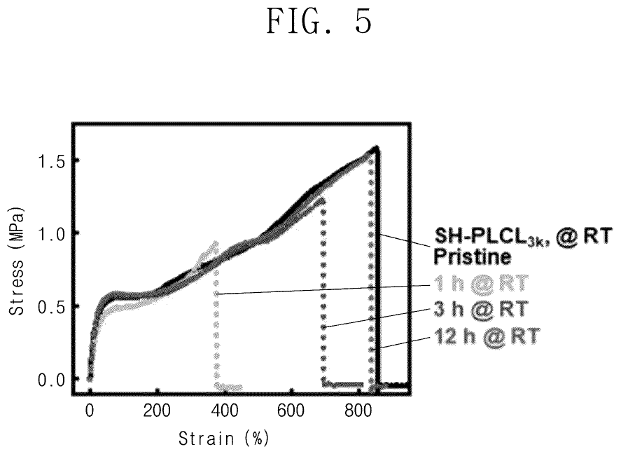

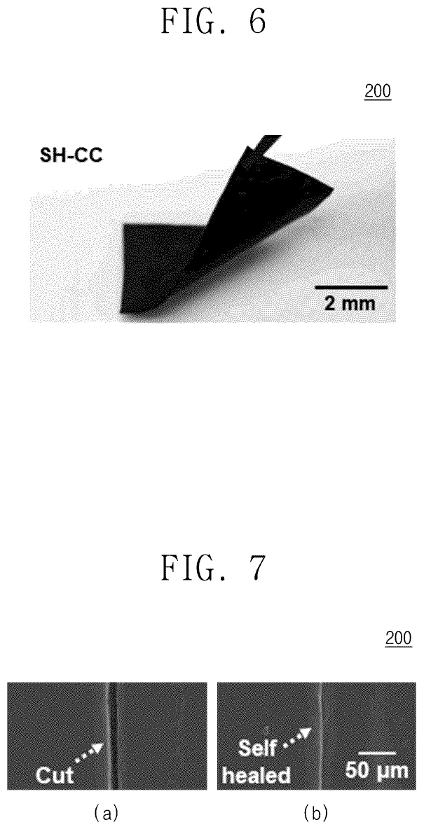

FIG. 6 is a photograph showing the first electrode pattern according to the embodiment of the present invention; and FIG. 7 is an SEM image showing a change in a section in which the first electrode pattern 200 of FIG. 6 is cut. FIGS. 7(a) and 7(b) show changes in the cut section.

Referring to FIGS. 6 and 7, the first electrode pattern 200 according to the embodiment of the present invention has flexibility, and boundaries of the cut section may be self-bonded when being physically cut.

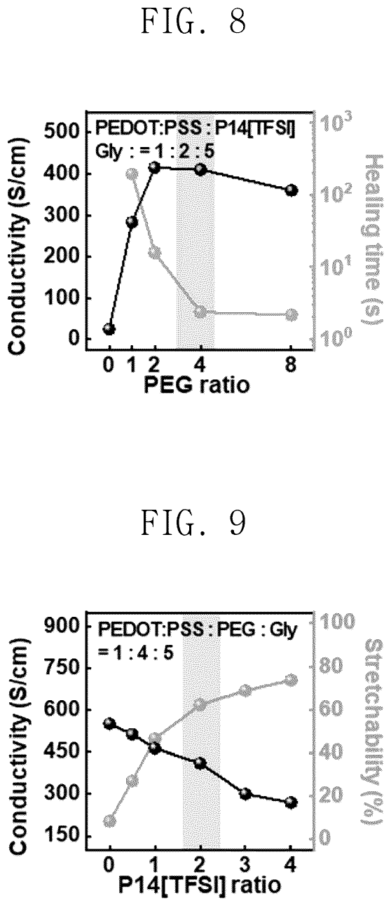

FIG. 8 is a graph showing electrical conductivity and recovery time of electrode patterns 200 and 400 measured by varying the ratio of polyethylene glycol (PEG).

The ratio of (PEDOT:PSS):P14[TFSI]:glycerol is 1:2:5, and PEG contents are set as [Table 1] to form electrode patterns. Thereafter, each of the electrode patterns is cut, electrical conductivity is measured and then recovery time is observed.

TABLE 1

| Items | PEDOT:PSS | P14[TFSI] | Glycerol | PEG |
|---|---|---|---|---|
| 1 | 1 | 2 | 5 | 0 |
| 2 | 1 | 2 | 5 | 1 |
| 3 | 1 | 2 | 5 | 2 |
| 4 | 1 | 2 | 5 | 4 |
| 5 | 1 | 2 | 5 | 8 |

Referring to FIG. 8, it is found that when PEG is not contained, the electrical conductivity is measured to be less than 20 S/cm and self-healing is not observed after cutting.

It is found that when the ratio of PEG is contained as 1, the electrical conductivity is measured to be less than 300 S/cm, and it took about 100 seconds or more for recovery after cutting.

It is found that when the ratio of PEG is contained as 2, the electrical conductivity is measured to be 400 S/cm or more, and it took about 10 seconds or more for recovery after cutting.

It is found that when the ratio of PEG is contained as 8, the electrical conductivity is measured to be about 350 S/cm, and it took less than about 5 seconds for recovery after cutting.

It is found that when the ratio of PEG is contained as 4 according to the embodiment of the present invention, the electrical conductivity is measured as about 400 S/cm and it takes less than about 5 seconds for recovery after cutting, and accordingly, high electrical conductivity and fast recovery time are implemented.

FIG. 9 is a graph showing electrical conductivity and stretchability of electrode patterns 200 and 400 measured by varying the P14[TFSI] ratio.

The ratio of (PEDOT:PSS):polyethylene glycol (PEG):glycerol is 1:4:5, P14[TFSI] contents are set as [Table 2] to form electrode patterns, and then electrical conductivity and stretchability are measured.

TABLE 2

| Items | PEDOT:PSS | PEG | Glycerol | P14[TFSI] |
|---|---|---|---|---|
| 1 | 1 | 4 | 5 | 0 |
| 2 | 1 | 4 | 5 | 1 |
| 3 | 1 | 4 | 5 | 2 |
| 4 | 1 | 4 | 5 | 3 |
| 5 | 1 | 4 | 5 | 4 |

Referring to FIG. 9, it is shown that when P14[TFSI] is not contained, electrical conductivity is less than 600 S/cm and stretchability is up to about 10%.

It is shown that when the ratio of P14[TFSI] is contained as 1, the electrical conductivity is 450 S/cm and the stretchability is up to about 40%.

It is shown that when the ratio of P14[TFSI] is contained as 3, the electrical conductivity is 300 S/cm and the stretchability is up to about 70%.

It is shown that when the ratio of P14[TFSI] is contained as 4, the electrical conductivity is less than 300 S/cm and the stretchability is up to about 75%.

It is shown that when the ratio of P14[TFSI] is contained as 2 according to the embodiment of the present invention, the electrical conductivity is less than 450 S/cm and the stretchability is up to about 70%, and accordingly, high electrical conductivity and high stretchability are implemented.

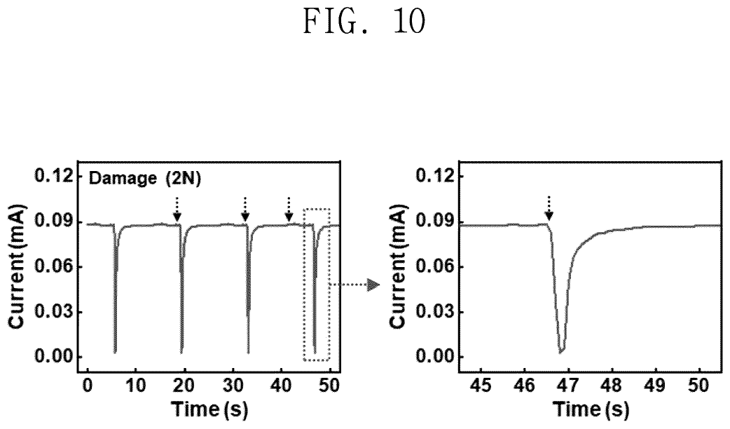

FIG. 10 is a graph measuring changes in current when repeated damage occurs to the first electrode pattern 200 according to the embodiment of the present invention. For measurement, a force of 2N is applied to the first electrode pattern 200 using a single-edged knife, thereby causing multiple times of damages to the first electrode pattern 200.

Referring to FIG. 10, it is confirmed that when repeated damage is generated, the first electrode pattern 200 has a current that decreases each time the damage occurs, however, the current increases again within a short period of time and returns to the level before the damage. Even when the first electrode pattern 200 is damaged by an external force and the electrical conductivity decreases, the electrical conductivity may recover to the level before the damage within several seconds.

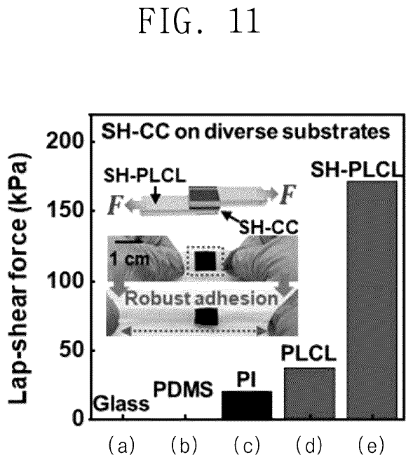

FIG. 11 is a view showing results of a lap-shear test of electronic devices 10 using the self-healing biodegradable elastic conductor accordingly to comparative examples and the embodiments of the present invention.

In the first comparative example (a), glass is used as the first base film 100 and the second base film, an electrode pattern is formed between the first base film and the second base film by using the conductive polymer solution, and then an annealing treatment is performed to manufacture a specimen in which the electrode pattern is provided between the upper and lower glasses.

In the second comparative example (b), PDMS is used as the first base film and the second base film, an electrode pattern is formed between the first base film and the second base film by using the conductive polymer solution, and then an annealing treatment is performed to manufacture a specimen in which the electrode pattern is provided between the upper and lower PDMSs.

In the third comparative example (c), polyimide (PI) is used as the first base film and the second base film, an electrode pattern is formed between the first base film and the second base film by using the conductive polymer solution, and then an annealing treatment is performed to manufacture a specimen in which the electrode pattern is provided between the upper and lower PIs.

In the fourth comparative example (d), poly(L-lactide-co-ε-caprolactone) (PLCL) is used as the first base film and the second base film, and an electrode pattern is formed between the first base film and the second base film by using the conductive polymer solution to manufacture a specimen in which the electrode pattern is provided between the upper and lower PLCLs.

In the embodiment (e) of the present invention the first base film SH-PLCL and the second base film SH-PLCL are manufactured by bonding isophorone diisocyanate (IPDI) to both ends of poly(L-lactide-co-ε-caprolactone) (PLCL), and then bonding Bis(4-aminophenyl)disulfide molecule (AFD) as a chain extender to both ends of IPDI, and an electrode pattern SH-CC is formed between the first base film SH-PLCL and the second base film SH-PLCL by using the conductive polymer solution and an annealing treatment is performed, thereby manufacturing a specimen in which the electrode pattern is provided between the first base film SH-PLCL and the second base film SH-PLCL.

The shear strength is measured by stretching both ends of the specimens (a to e) in the outward direction F.

Referring to FIG. 11, the specimens (a and b) according to the first and second comparative examples are measured to have an adhesive strength (lap-shear force (kPa)) close to 0, the specimen (c) according to the third comparative example is measured to have an adhesive strength of about 25 kPa, and the specimen (d) according to the fourth comparative example is measured to have an adhesive strength of about 50 kPa.

Whereas, it is confirmed that the specimen (e) according to the embodiment of the present invention is measured to have an adhesive strength of about 160 kPa, thereby exhibiting high shear strength, and accordingly a robust adhesion is formed between the first base film SH-PLCL, the electrode pattern SH-CC, and the second base film SH-PLCL.

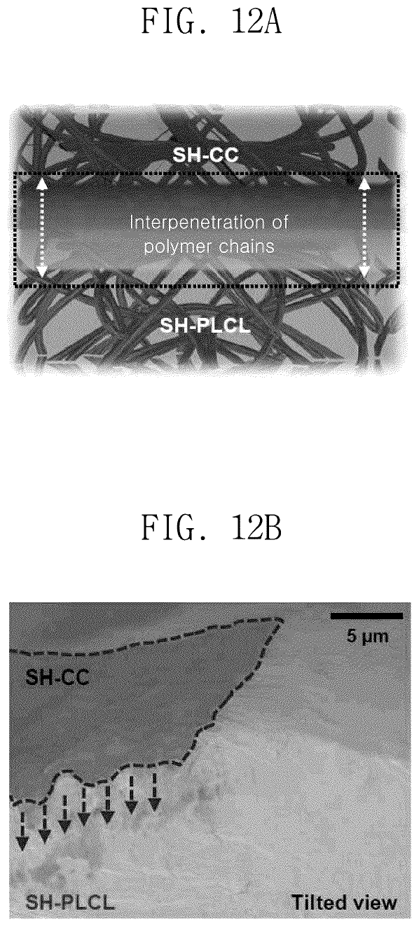

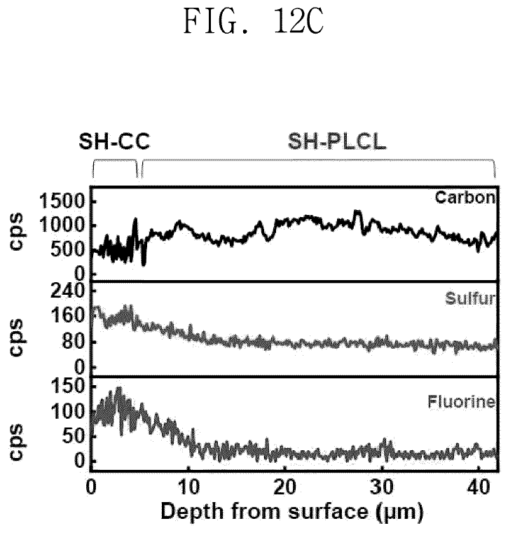

FIG. 12A to 12C are views showing physical bonding between the first base film SH-PLCL 100 and the first electrode pattern SH-CC 200 according to the embodiment of the present invention. FIG. 12(a) shows an image of the bond between the first base film SH-PLCL 100 and the first electrode pattern SH-CC 200; FIG. 12(b) shows an SEM image of an interface between the first base film SH-PLCL 100 and the first electrode pattern SH-CC 200; and FIG. 12(c) shows elemental analysis results of the first base film SH-PLCL 100 and the first electrode pattern SH-CC 200.

Referring to FIG. 12A to 12C, interfaces between the first base film SH-PLCL 100 and the first electrode pattern SH-CC 200 are physically bonded by interpenetration of polymer chains. In the SEM image of the interface between the first base film SH-PLCL 100 and the first electrode pattern SH-CC 200, a section having apparently unclear and diffused shape is observed at the interface between the first electrode pattern SH-CC 200 and the first base film SH-PLCL 100 having a thickness of 5 μm. Based on the elemental analysis results of the first base film SH-PLCL 100 and the first electrode pattern SH-CC 200, large amounts of fluorine element present only in the first electrode pattern SH-CC 200 are found at the interface between the first base film SH-PLCL 100 and the first electrode pattern SH-CC 200. This indicates that the physical bond is formed due to the interpenetration between the first base film SH-PLCL 100 and the first electrode pattern SH-CC 200.

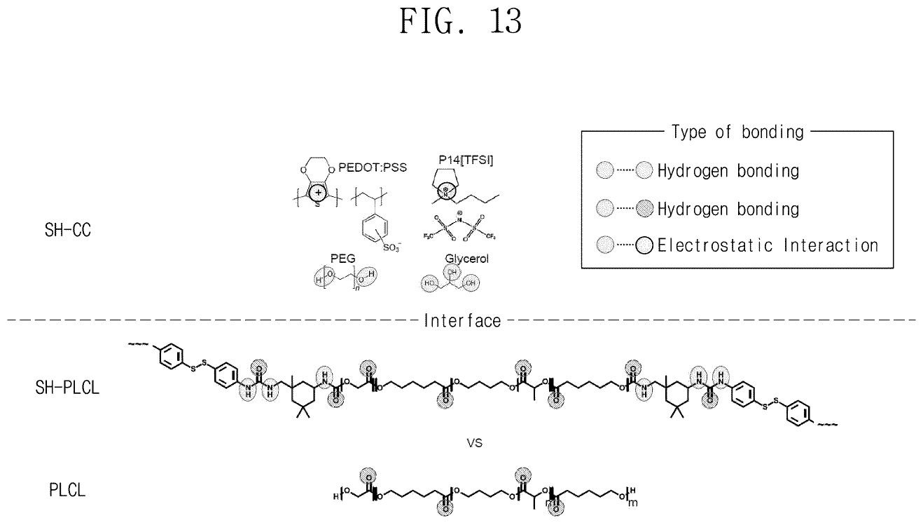

FIG. 13 is a view showing molecular structures of the first base film SH-PLCL 100 and the first electrode pattern SH-CC 200 according to the embodiment of the present invention.

Referring to FIG. 13, the first base film SH-PLCL 100 has a plurality of hydrogen bonding sites, and the first electrode pattern SH-CC 200 also has hydrogen bonding sites including polyethylene glycol (PEG) and glycerol. When the first base film SH-PLCL 100 and the first electrode pattern SH-CC 200 are bonded, a plurality of hydrogen bondings are formed at the interfaces through the hydrogen bonding sites, and accordingly, chemical bonding occurs.

As described above, the first base film SH-PLCL 100 and the first electrode pattern SH-CC 200 may form a robust adhesion by the physical bonding due to the interpenetration of polymer chains and the chemical bonding due to the hydrogen bonding at the hydrogen bonding sites at the bonding surface between the first base film SH-PLCL 100 and the first electrode pattern SH-CC 200.

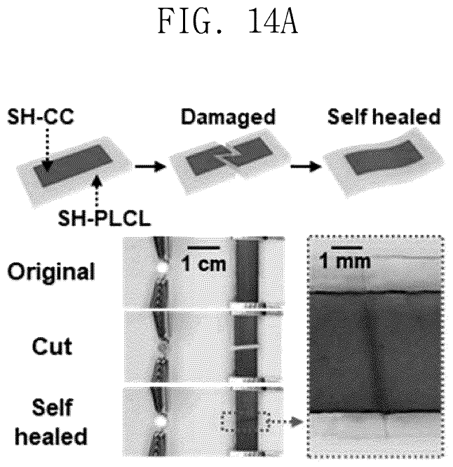

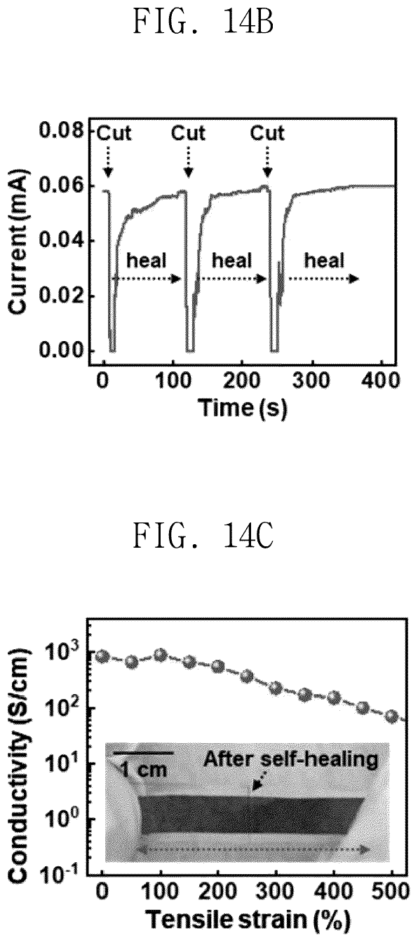

FIG. 14A to 14C are views showing results of a self-healing ability experiment of a specimen manufactured according to the embodiment of the present invention. FIG. 14A is an image showing changes in cut section of the specimen; FIG. 14B is a graph measuring changes in current when repeated damage occurs in the specimen; and FIG. 14C shows tensile strain-conductivity of the specimen recovered after cutting.

Referring to (a), a specimen is fabricated by connecting the self-healing biodegradable elastic conductor manufactured using the first base film SH-PLCL 100 and the first electrode pattern SH-CC 200 according to the embodiment of the present invention to a light-emitting diode (LED) to provide electrical connection to the LED, and afterwards, the specimen is cut and its changes are observed. A current supplied to the LED decreases due to the cutting of the specimen, however, the cut surface of the specimen is self-bonded for 1 minute and recovers the electrical characteristics before the cutting.

Referring to (b), the specimen is healed repeatedly with respect to repeated cutting, and recovers the previous level of conductivity within about 2 minutes.

Referring to (c), it is found that the specimen is stretchable up to 500% in a cut and self-healed state. In addition, it is indicated that when the self-healed specimen is stretched after cutting, the electrical conductivity gradually decreases and about 10% of the initial conductivity is maintained.

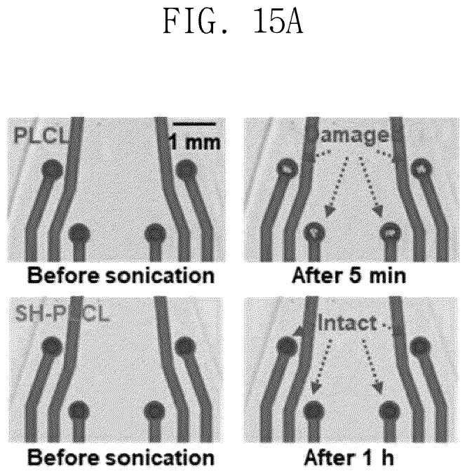

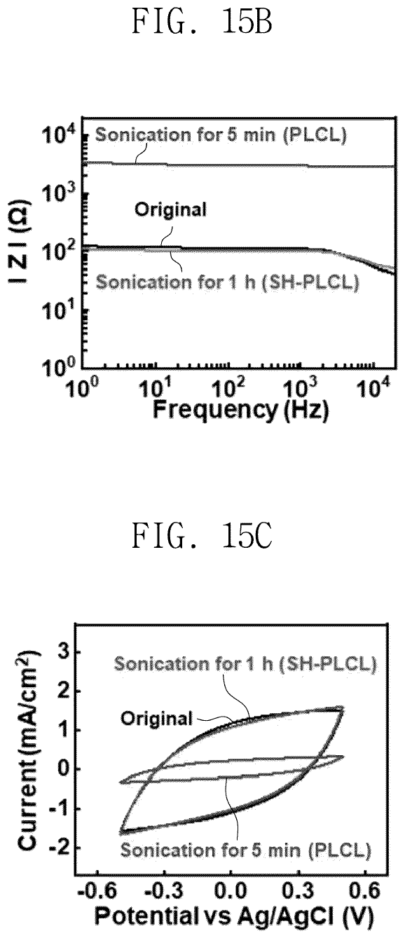

FIG. 15A to 15C are views showing results of testing physical and electrical stability under aqueous conditions of electronic devices using self-healing biodegradable elastic conductors according to the embodiment of the present invention and the comparative example. FIG. 15A is an image showing changes in electrode pattern subject to sonication after the electrical devices according to the embodiment of the present invention and the comparative examples are immersed in a phosphate buffered saline solution; FIG. 15B shows impedance measurement results of the electric devices according to the embodiment of the present invention and the comparative examples after the sonication; and FIG. 15C shows cyclic voltammetry curves after the sonication of the electrical devices according to the embodiment of the present invention and the comparative examples.

The specimen PLCL according to the comparative example is manufactured by forming a base film with PLCL and fabricated by forming an electrode pattern on an upper surface of PLCL with the conductive solution.

The specimen SH-PLCL according to the embodiment of the present invention is fabricated after manufacturing a base film using a polymer obtained by bonding isophorone diisocyanate (IPDI) to both ends of poly (L-lactide-co-ε-caprolactone) (PLCL), and then bonding Bis(4-aminophenyl)disulfide molecule (AFD) as a chain extender to both ends of IPDI, and after forming an electrode pattern using the conductive solution.

Thereafter, the specimen SH-PLCL according to the embodiment of the present invention and the specimen PLCL according to the comparative example are immersed in phosphate buffered saline solutions PBS at pH 7 and sonicated.

Referring to (a), the specimen PLCL according to the comparative example shows that the electrode pattern is damaged and delaminated by the sonication for 5 minutes, whereas the specimen SH-PLCL according to the embodiment of the present invention shows that the electrode pattern is maintained without damage even after the sonication for 1 hour.

Referring to (b), the specimen SH-PLCL according to the embodiment of the present invention and the specimen PLCL according to the comparative example show that the impedances are almost identical before and after phosphate buffered saline solution and sonication. The specimen PLCL according to the comparative example maintains in high impedance subject to frequency changes upon sonication for 5 minutes in the phosphate buffered saline solution, whereas the specimen SH-PLCL according to the embodiment of the present invention has an impedance that remains almost the same regardless of frequency changes before and after sonication for 1 hour in the phosphate buffered saline solution.

Referring to (c), the specimen SH-PLCL according to the embodiment of the present invention and the specimen PLCL according to the comparative example are found to have the same charge storage capacity of 1.7 mA/cm2 before the phosphate buffered saline solution and the sonication. It can be found that the specimen PLCL according to the comparative example has the charge storage capacity significantly decreasing upon sonication for 5 minutes in the phosphate buffered saline solution.

Whereas, in the specimen SH-PLCL according to the embodiment of the present invention, almost no change is found before and after sonication for 1 hour in the phosphate buffered saline solution.

Accordingly, the electronic device 10 using the self-healing biodegradable elastic conductor according to the embodiment of the present invention may be applied in humid environments and physiological conditions (pH7, 37° C.) and stably detect electrical changes.

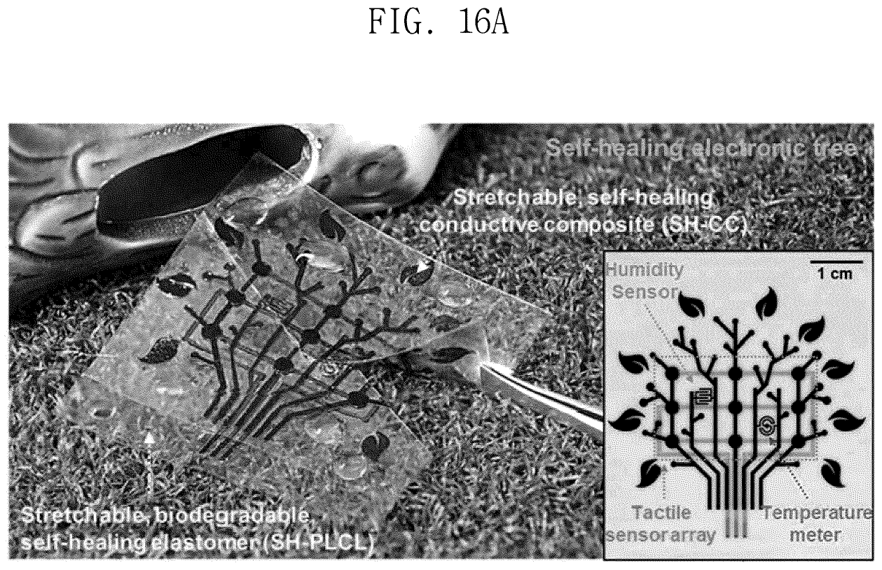

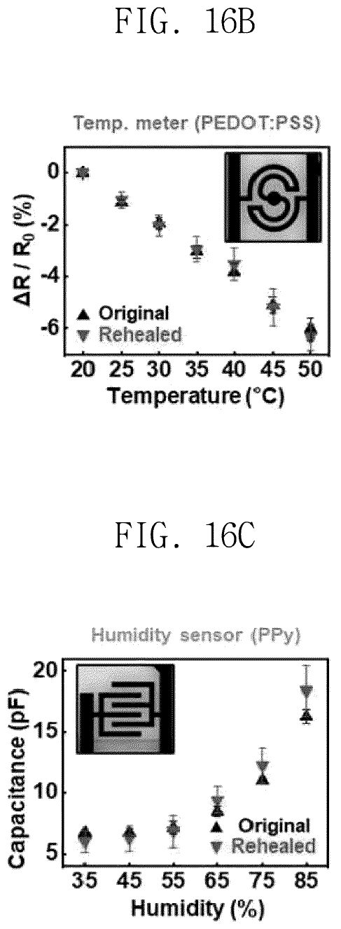

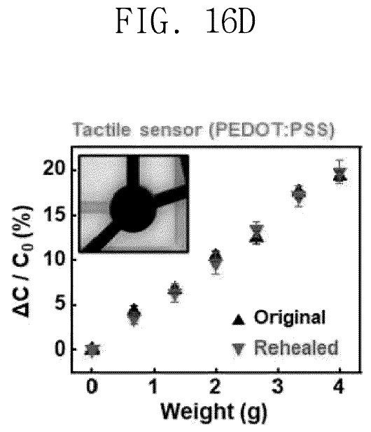

FIG. 16A to 16D are views showing the electronic device 10 using the self-healing biodegradable elastic conductor according to the embodiment of the present invention. FIG. 16A is an enlarged image of the electronic device 10 using the self-healing biodegradable elastic conductor according to the embodiment of the present invention; FIG. 16B shows changes in electrical performance of a temperature sensor after self-healing of the electronic device 10 using the self-healing biodegradable elastic conductor; FIG. 16C shows changes in electrostatic capacity of a humidity sensor after self-healing of the electronic device 10 using the self-healing biodegradable elastic conductor; and FIG. 16D shows changes in electrical performance of a pressure sensor after self-healing of the electronic device 10 using the self-healing biodegradable elastic conductor.

In the electronic device 10 using the self-healing biodegradable elastic conductor according to the embodiments of the present invention, the temperature sensor, the humidity sensor, and the pressure sensor are cut using a razor blade and the changes after self-healing are observed to measure the performance changes after self-healing.

Referring to FIG. 16A to 16D, in the electronic device 10 using the self-healing biodegradable elastic conductor according to the embodiments of the present invention, it is found that sensitivities of the temperature, humidity and pressure sensors remained almost the same before and after the physical damage self-healed.

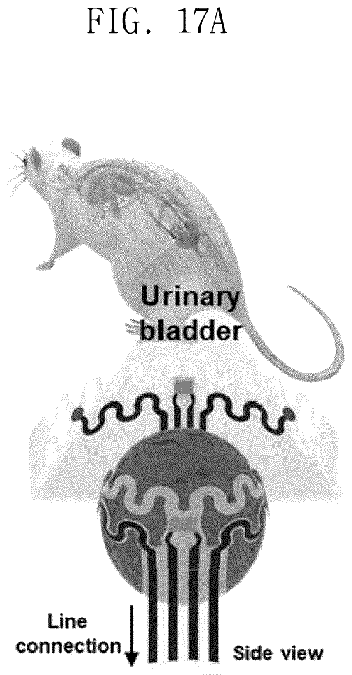

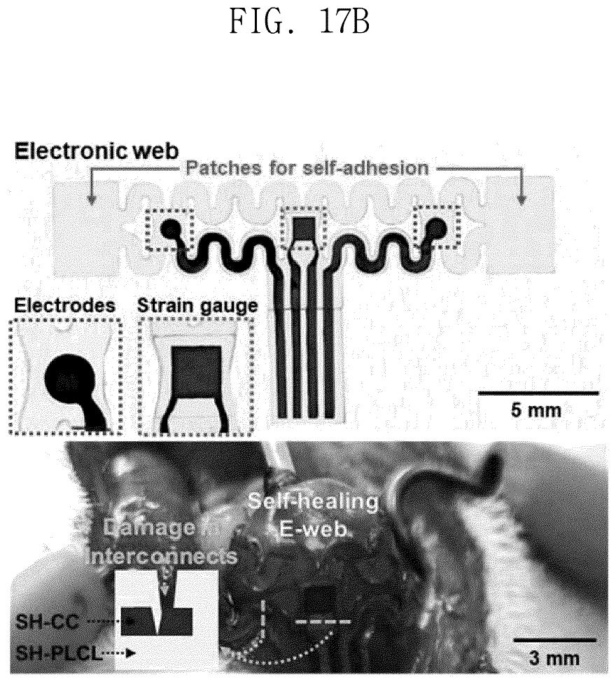

FIGS. 17A and 17B are views showing a state in which the electronic device 10 using the self-healing biodegradable elastic conductor according to the embodiment of the present invention is applied inside a living body.

Referring to FIGS. 17A and 17B, the electronic device using the self-healing biodegradable elastic conductor according to the embodiments of the present invention may be implanted into a bladder in a living body to monitor physiological functions of the bladder. The electronic device 10 using the self-healing biodegradable elastic conductor may be formed of soft and flexible material and installed in the bladder without sutures to monitor the physiological functions of the bladder.

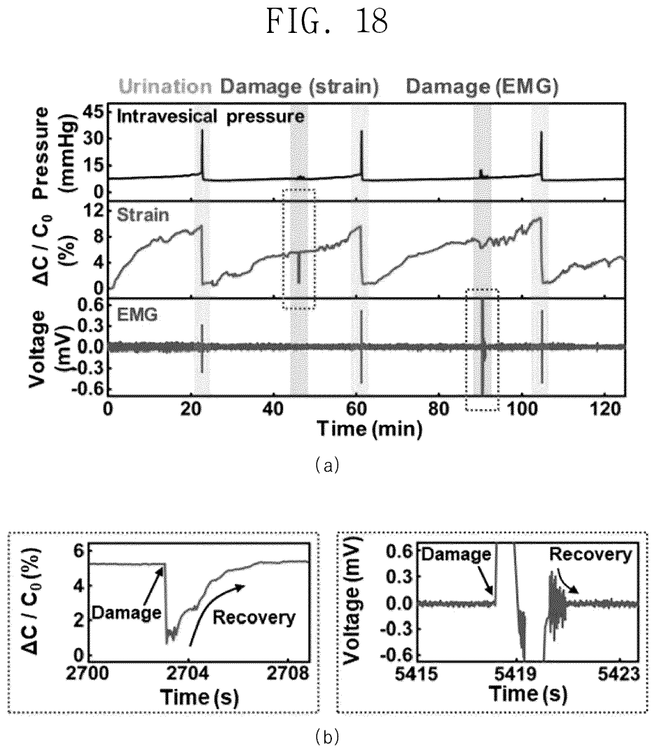

FIG. 18 is a graph showing results of functional recovery for artificial damage to the electric device 10 using the self-healing biodegradable elastic conductor of FIG. 17 while monitoring urination behaviors of a bladder in real time through the electric device. FIG. 18(a) shows changes in intravesical pressure, strain and electromyography (EMG) for damage to the electronic device 10 using the self-healing biodegradable elastic conductor; and FIG. 18(b) shows a damage and recovery process of a strain sensor and an electromyography sensor when damage occurs in the electronic device 10 using the self-healing biodegradable elastic conductor.

Referring to FIG. 18, it is confirmed that while the electronic device 10 using the self-healing biodegradable elastic conductor and implanted in the bladder is monitoring the urination process periodically through strain and electromyography signals, and when the strain sensor or EMG sensor is intentionally damaged, the signal from the strain sensor or EMG sensor is immediately interrupted due to the damage, but quickly recovered within 5 seconds.

Although the present invention has been described in detail with reference to the preferred embodiments, the present invention is not limited to the specific embodiments and will be interpreted by the following claims. In addition, it will be apparent that a person having ordinary skill in the art may carry out various deformations and modifications for the embodiments described as above within the scope without departing from the present invention.

What is claimed is:

1. A method of manufacturing an electronic device, the method comprising:
preparing a base film;
forming an electrode pattern by spin-coating a conductive polymer solution on the base film; and
annealing the electrode pattern, wherein
the base film is manufactured from a polymer formed by bonding diisocyanate to both ends of a biodegradable polymer and bonding a chain extender having a disulfide bond structure to an end of the diisocyanate, and the conductive polymer solution includes a mixed solution of a conductive polymer, an ionic liquid, polyethylene glycol, and glycerol.

2. The method of claim 1, wherein the biodegradable polymer includes poly(L-lactide-co-ε-caprolactone) (PLCL), the diisocyanate includes isophorone diisocyanate (IPDI), and the chain extender includes Bis(4-aminophenyl)disulfide molecule (AFD).

3. The method of claim 2, wherein the conductive polymer includes at least one selected from PEDOT:PSS, polypyrrole (PPy), and polyaniline (PANI), and the ionic liquid includes P14[TFSI](N-methyl-N-butylpyrrolidinium bis(trifluoromethanesulfonyl)imide).

4. The method of claim 1, wherein the conductive polymer, the ionic liquid, the polyethylene glycol, and the glycerol are mixed in a ratio of 1:2:4:5.

5. The method of claim 1, wherein the annealing includes heat-treating the base film and the electrode pattern at a temperature range of 130° C. to 150° C.

6. The method of claim 1, wherein the base film has a thickness of 10 μm to 500 μm, and the electrode pattern has a thickness of 0.1 μm to 5 μm.

7. An electronic device comprising:
a first base film; and
a first electrode pattern adhering to an upper surface of the first base film, wherein
the first base film is manufactured from a polymer formed by bonding diisocyanate to both ends of a biodegradable polymer and bonding a chain extender having a disulfide bond structure to an end of the diisocyanate, and
the first electrode pattern is formed by spin-coating a conductive polymer solution obtained by mixing a conductive polymer, an ionic liquid, polyethylene glycol, and glycerol onto the upper surface of the first base film.

8. The electronic device of claim 7, further comprising:
a second base film provided on an upper portion of the first electrode pattern; and
a second electrode pattern adhering to an upper surface of the second base film, wherein
the second base film is manufactured from a polymer formed by bonding diisocyanate to both ends of a biodegradable polymer and bonding a chain extender having a disulfide bond structure to an end of the diisocyanate, and
the second electrode pattern is formed by spin-coating a conductive polymer solution obtained by mixing a conductive polymer, an ionic liquid, polyethylene glycol, and glycerol onto the upper surface of the second base film.

9. The electronic device of claim 8, wherein the biodegradable polymer includes poly(L-lactide-co-ε-caprolactone) (PLCL), the diisocyanate includes isophorone diisocyanate (IPDI), the chain extender includes Bis(4-aminophenyl)disulfide molecule (AFD), the conductive polymer includes at least one selected from PEDOT:PSS, polypyrrole (PPy), and polyaniline (PANI), and the ionic liquid includes P14[TFSI](N-methyl-N-butylpyrrolidinium bis(trifluoromethanesulfonyl)imide).

10. The electronic device of claim 8, wherein the first base film has a thickness of 10 μm to 500 μm, and the first electrode pattern has a thickness of 0.1 μm to 5 μm.
